(19) United States
(12) Patent Application Publication
(10) Pub. No.: US 2024/0039511 A1
(43) Pub. Date: Feb. 1, 2024

(54) Vibrator And Vibrator Device

(71) Applicant: SEIKO EPSON CORPORATION, Tokyo (JP)

(72) Inventors: Kensaku ISOHATA, Minowa (JP); Atsushi MATSUO, Shiojiri (JP); Norihito MATSUKAWA, Shimosuwa (JP)

(21) Appl. No.: 18/360,385

(22) Filed: Jul. 27, 2023

(30) Foreign Application Priority Data
Jul. 28, 2022 (JP) 2022-120270

(51) Int. Cl. H03H 9/13; H03H 9/05; H03H 9/10; H03H 9/19

(52) U.S. Cl. CPC H03H 9/132; H03H 9/0509; H03H 9/1021; H03H 9/19

(57) ABSTRACT

A vibrator includes a vibrator section, a support section, a linkage section, a first excitation electrode that is provided at a first principal surface, a second excitation electrode that is provided at a second principal surface and induces along with the first excitation electrode thickness-shear vibration that vibrates along a direction X, a first support electrode that is provided at the support section and electrically coupled to the first excitation electrode, a second support electrode that is provided at the support section and electrically coupled to the second excitation electrode, a first draw-out wiring line that is drawn from the first excitation electrode along a direction Z and electrically couples the first excitation electrode to the first support electrode, and a second draw-out wiring that is drawn from the second excitation electrode along the direction Z and electrically couples the second excitation electrode to the second support electrode.

The present application is based on, and claims priority from JP Application Serial Number 2022-120270, filed Jul. 28, 2022, the disclosure of which is hereby incorporated by reference herein in its entirety.

### BACKGROUND

### 1. Technical Field

The present disclosure relates to a vibrator and a vibrator device.

### 2. Related Art

JP-A-2015-186196 discloses the configuration of a piezoelectric vibrator element including a vibrator section provided with a pair of excitation electrodes, a support section extending away from the vibrator section, and a linkage section extending to link one end of the support section to the end of the vibrator section, with draw-out wiring lines respectively drawn from the pair of excitation electrodes to a joint surface of the support section so that the effect of support stress on the vibration is suppressed.

The technology described in JP-A-2015-186196, however, involves drawing the draw-out wiring lines in the direction X, which is the direction in which thickness-shear vibration occurs from the vibrator section, so the vibration affects the draw-out wiring lines and may result in deterioration in the vibration characteristics of the piezoelectric vibrator element.

### SUMMARY

A vibrator includes a vibrator section that has a first principal surface, a second principal surface that is opposite from the first principal surface, a first side surface that couples the first principal surface and the second principal surface to each other and extends along a first direction, and a second side surface that couples the first principal surface and the second principal surface to each other and extends along a second direction that intersects with the first direction; a support section that is disposed at a distance from the vibrator section and has a first support side surface facing the first side surface of the vibrator section and extending along the first direction and a second support side surface extending along the second direction; a linkage section that has a first linkage surface coupled to the first side surface and the first support side surface and a second linkage surface coupled to the second side surface and the second support side surface; a first excitation electrode that is provided at the first principal surface; a second excitation electrode that is provided at the second principal surface and induces along with the first excitation electrode thickness-shear vibration that vibrates along the second direction; a first support electrode that is provided at the support section and electrically coupled to the first excitation electrode; a second support electrode that is provided at the support section and electrically coupled to the second excitation electrode; a first draw-out wiring line that is drawn from the first excitation electrode along the first direction and electrically couples the first excitation electrode to the first support electrode; and a second draw-out wiring that is drawn from the second excitation electrode along the first direction and electrically couples the second excitation electrode to the second support electrode.

A vibrator device includes the vibrator described above, a base on which the vibrator is mounted, and a container that houses the vibrator, and the support section of the vibrator is joined to the base via a joining material.

### BRIEF DESCRIPTION OF THE DRAWINGS

FIG. 1 is a plan view showing the configuration of a vibrator device.

FIG. 2 is a cross-sectional view of the vibrator device shown in FIG. 1 taken along the line A-A.

FIG. 3 is a plan view showing the configuration of a vibrator.

FIG. 4 is a cross-sectional view of the vibrator shown in FIG. 3 taken along the line B-B.

FIG. 5 is a plan view showing the configuration of a vibrator according to a variation.

FIG. 6A is a plan view showing the configuration of a vibrator according to another variation.

FIG. 6B is a side view showing the configuration of the vibrator shown in FIG. 6A.

FIG. 6C is another side view showing the configuration of the vibrator shown in FIG. 6A.

FIG. 7A is a plan view showing the configuration of a vibrator according to another variation.

FIG. 7B is a side view showing the configuration of the vibrator shown in FIG. 7A.

FIG. 7C is another side view showing the configuration of the vibrator shown in FIG. 7A.

FIG. 8A is a plan view showing the configuration of a vibrator according to another variation.

FIG. 8B is a side view showing the configuration of the vibrator shown in FIG. 8A.

### DESCRIPTION OF EXEMPLARY EMBODIMENTS

In the following drawings, the description will be made by using three axes called axes X, Y, and Z perpendicular to one another. The direction along the axis X is called a “direction X”, the direction along the axis Y is called a “direction Y”, and the direction along the axis Z is called a “direction Z”, with the direction indicated by the arrow is the direction toward the positive end of the axis, and the direction opposite the direction toward the positive end is the direction toward the negative end of the axis.

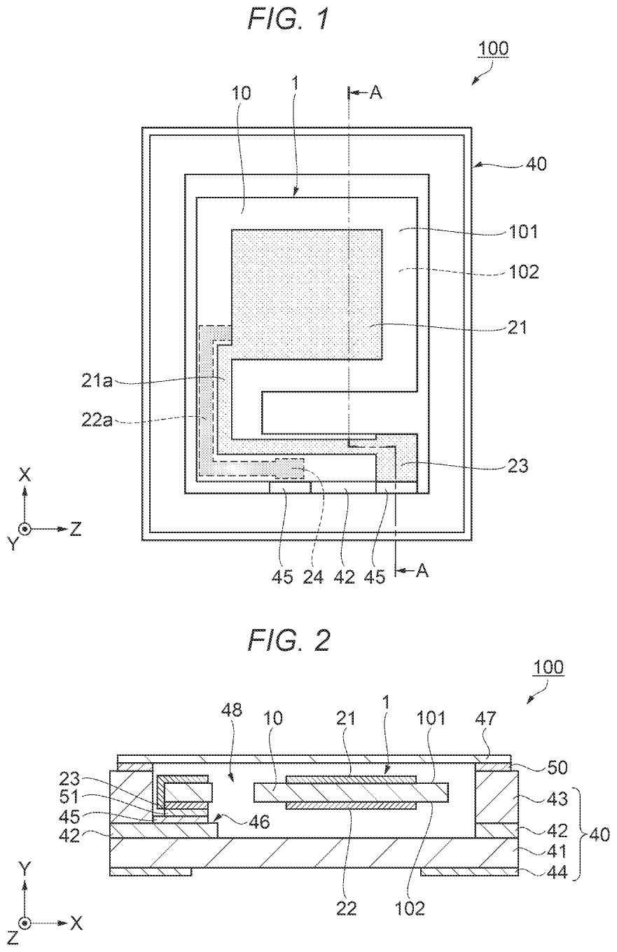

The configuration of a vibrator device 100 will first be described with reference to FIGS. 1 and 2. A lid 47 is omitted in FIG. 1 for convenience of the description.

The vibrator device 100 includes a vibrator 1, a container 40, which is made of ceramic or any other material and houses the vibrator 1, and a lid 47 made of glass, ceramic, metal, or any other material, as shown in FIGS. 1 and 2.

The container 40 is formed by stacking an implementation terminal 44, a first substrate 41, a second substrate 42, and a third substrate 43 on each other, as shown in FIG. 2. In the present embodiment, the second substrate 42 is a base on which a vibrator element 10, that is, the vibrator 1, is mounted.

The container 40 has a cavity 48, which opens upward. The interior of the cavity 48, which houses the vibrator 1, is hermetically sealed in the form of a reduced-pressure atmosphere or an inert gas atmosphere, such as a nitrogen atmosphere, when the lid 47 is joined to the container 40 via a joining member 50, such as a sealing ring.

The implementation terminal 44 is actually formed of a plurality of implementation terminals 44 provided at the outer bottom surface of the first substrate 41. The implementation terminals 44 are electrically coupled to coupling terminals 45, which are provided on the second substrate 42, via through-via electrodes and interlayer wiring lines that are not shown.

The vibrator 1 is housed in the cavity 48 of the container 40. In the vibrator 1, support electrodes 23 and 24, which are provided at a support section 120 (see FIG. 3), are joined and electrically coupled to the coupling terminals 45, which are provided at a mounting surface 46 of the second substrate 42, which is the base, via a joining material 51, such as an electrically conductive adhesive.

The joining material 51 includes a first electrically conductive adhesive and a second electrically conductive adhesive. The first electrically conductive adhesive electrically couples a first excitation electrode 21 to the second substrate 42. The second electrically conductive adhesive electrically couples a second excitation electrode 22 to the second substrate 42. That is, the excitation electrodes 21 and 22 of the vibrator 1 and the implementation terminals 44 provided at the container 40 are electrically coupled to each other via the support electrodes 23 and 24, the joining material 51, the coupling terminals 45, and other components.

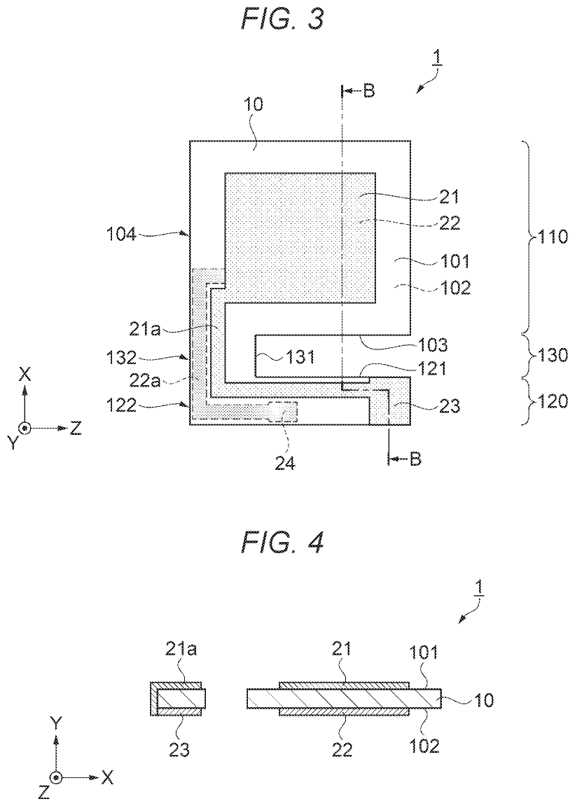

The configuration of the vibrator 1 will next be described with reference to FIGS. 3 and 4.

The vibrator 1 includes the vibrator element 10, the first excitation electrode 21, the second excitation electrode 22, the first support electrode 23, and the second support electrode 24, as shown in FIGS. 3 and 4.

The vibrator element 10 is capable of thickness-shear vibration and is made of any of a variety of piezoelectric materials, including a quartz crystal element as a representative example. The vibrator element 10 is typically an AT-cut quartz crystal element, or a two-turn-cut quartz crystal element, a representative example of which is an SC-cut quartz crystal element. In the present embodiment, the vibrator element 10 is an AT-cut quartz crystal element having a quadrangular planar shape, specifically, an oblong planar shape. The directions toward the positive ends of the axes X, Y, and Z in FIGS. 3 and 4 therefore coincide with the directions toward the positive ends of axes X, Y′, and Z′ that are the crystallographic axes of quartz crystal, respectively. The definition described above is not necessarily employed, and the direction toward the positive end of at least one of the axes X, Y, and Z may coincide with the direction toward the negative end.

The vibrator element 10 is a rectangular planar plate having a lengthwise direction that coincides with the direction X and a widthwise direction that coincides with the direction Z. The vibrator element 10 includes a vibrator section 110, the support section 120, which is disposed at a distance from the vibrator section 110, and a linkage section 130, which links the vibrator section 110 to the support section 120.

The vibrator section 110 has a first principal surface 101, a second principal surface 102, which is opposite from the first principal surface 101, a first side surface 103, which couples the first principal surface 101 and the second principal surface 102 to each other and extends along the direction Z, which is a first direction, and a second side surface 104, which couples the first principal surface 101 and the second principal surface 102 to each other and extends along the direction X, which is a second direction that intersects with the direction Z.

The support section 120 has a first support side surface 121, which is disposed so as to face the first side surface 103 of the vibrator section 110 and extends along the direction Z, and a second support side surface 122 extending along the direction X.

The linkage section 130 has a first linkage surface 131 coupled to the first side surface 103 and the first support side surface 121, and a second linkage surface 132 coupled to the second side surface 104 and the second support side surface 122.

The first excitation electrode 21 is provided substantially at the center of the first principal surface 101 of the vibrator element 10. The second excitation electrode 22 is provided substantially at the center of the second principal surface 102 of the vibrator element 10 so as to coincide with the first excitation electrode 21 in the plane view. Specifically, the second excitation electrode 22 along with the first excitation electrode 21 induces thickness-shear vibration that vibrates along the direction X.

The first excitation electrode 21 is electrically coupled to the first support electrode 23 via a first draw-out wiring line 21a. The second excitation electrode 22 is electrically coupled to the second support electrode 24 via a second draw-out wiring line 22a. The first support electrode 23 is electrically coupled to the first draw-out wiring line 21a, for example, via a through-via electrode provided through the vibrator element 10.

The first support electrode 23 is provided at the support section 120 and is electrically coupled to the first excitation electrode 21. The second support electrode 24 is provided at the support section 120 and is electrically coupled to the second excitation electrode 22.

The first draw-out wiring line 21a is drawn from the first excitation electrode 21 along the direction Z and electrically couples the first excitation electrode 21 to the first support electrode 23. Specifically, the first draw-out wiring line 21a is drawn from the first excitation electrode 21 toward the second side surface 104, which faces the negative end of the direction Z.

The second draw-out wiring line 22a is drawn from the second excitation electrode 22 along the direction Z and electrically couples the second excitation electrode 22 to the second support electrode 24. Specifically, the second draw-out wiring line 22a is drawn from the second excitation electrode 22 toward the second side surface 104, which faces the negative end of the direction Z.

As described above, the first draw-out wiring line 21a is drawn out from the first excitation electrode 21 toward the negative end of the direction Z and then electrically coupled to the first support electrode 23, and the second draw-out wiring line 22a is drawn out from the second excitation electrode 22 toward the negative end of the direction Z and then electrically coupled to the second support electrode 24, so that the effect of thickness-shear vibration induced in the direction X on the draw-out wiring lines 21a and 22a can be suppressed, whereby deterioration in the vibration characteristics of the vibrator element 10 can be suppressed. The vibration characteristics are, for example, a Q value (representing how easily vibration occurs) and a crystal impedance (CI) value (that is, resistance value of the vibrator 1).

Since the first draw-out wiring line 21a and the second draw-out wiring line 22a are drawn toward the second side surface 104, the draw-out wiring lines 21a and 22a from the excitation electrodes 21 and 22 to the support electrodes 23 and 24 can be shortened, so that the wiring resistance of the draw-out wiring lines 21a and 22a can be reduced.

As described above, the vibrator 1 according to the present embodiment includes the vibrator section 110, which has the first principal surface 101, the second principal surface 102, which is opposite from the first principal surface 101, the first side surface 103, which couples the first principal surface 101 and the second principal surface 102 to each other and extends along the direction Z, and the second side surface 104, which couples the first principal surface 101 and the second principal surface 102 to each other and extends along the direction X, which intersects with the direction Z, the support section 120, which is disposed at a distance from the vibrator section 110 and has the first support side surface 121, which faces the first side surface 103 of the vibrator section 110 and extends along the direction Z, and the second support side surface 122 extending along the direction X, and the linkage section 130, which has the first linkage surface 131 coupled to the first side surface 103 and the first support side surface 121 and the second linkage surface 132 coupled to the second side surface 104 and the second support side surface 122, and further includes the first excitation electrode 21 provided at the first principal surface 101, the second excitation electrode 22, which is provided at the second principal surface 102 and induces along with the first excitation electrode 21 thickness-shear vibration that vibrates along the direction X, the first support electrode 23 provided at the support section 120 and electrically coupled to the first excitation electrode 21, the second support electrode 24 provided at the support section 120 and electrically coupled to the second excitation electrode 22, the first draw-out wiring line 21a, which is drawn from the first excitation electrode 21 along the direction toward the negative end of the direction Z and electrically couples the first excitation electrode 21 to the first support electrode 23, and the second draw-out wiring line 22a, which is drawn from the second excitation electrode 22 along the direction toward the negative end of the direction Z and electrically couples the second excitation electrode 22 to the second support electrode 24.

According to the configuration described above, the first draw-out wiring line 21a is drawn from the first excitation electrode 21 toward the negative end of the direction Z and then electrically coupled to the first support electrode 23, and the second draw-out wiring line 22a is drawn from the second excitation electrode 22 toward the negative end of the direction Z and then electrically coupled to the second support electrode 24, so that the effect of thickness-shear vibration induced in the direction X on the draw-out wiring lines 21a and 22a can be suppressed, whereby deterioration in the vibration characteristics of the vibrator element 10 can be suppressed.

It is preferable in the vibrator 1 according to the present embodiment that the first draw-out wiring line 21a is drawn from the first excitation electrode 21 toward the second side surface 104, and that the second draw-out wiring line 22a is drawn from the second excitation electrode 22 toward the second side surface 104. According to the configuration described above, the draw-out wiring lines 21a and 22a from the excitation electrodes 21 and 22 to the support electrodes 23 and 24 can be shortened, so that the wiring resistance of the draw-out wiring lines 21a and 22a can be reduced.

As described above, the vibrator device 100 according to the present embodiment includes the vibrator 1 described above, the second substrate 42, on which the vibrator 1 is mounted, and the container 40, which houses the vibrator 1, and the support section 120 of the vibrator 1 is joined to the second substrate 42 via the joining material 51. According to the configuration described above, the vibrator device 100 having less affected vibration characteristics can be provided.

In the vibrator device 100 according to the present embodiment, the joining material 51 preferably includes the first electrically conductive adhesive, which electrically couples the first excitation electrode 21 provided at the first principal surface 101 to the second substrate 42, and the second electrically conductive adhesive, which electrically couples the second excitation electrode 22 provided at the second principal surface 102 to the second substrate 42. According to the configuration described above, since the joining material 51 includes the first electrically conductive adhesive and the second electrically conductive adhesive, electrical transmission from the first excitation electrode 21 and the second excitation electrode 22 to an external component and electrical reception from the external component can be performed.

Variations of the embodiment described above will be described below.

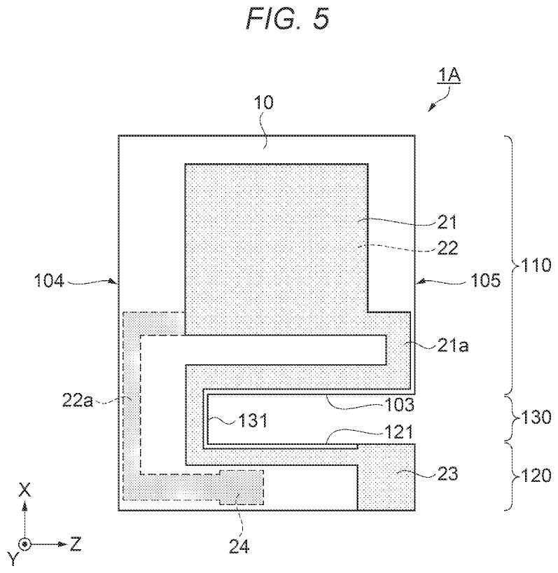

As described above, the method for drawing the first draw-out wiring line 21a from the first excitation electrode 21 and the second draw-out wiring line 22a from the second excitation electrode 22 is not limited to the method described in the embodiment described above and may be any of the methods shown in FIGS. 5 to 8B.

The first draw-out wiring line 21a of a vibrator 1A according to a variation shown in FIG. 5 is drawn from the first excitation electrode 21 toward the positive end of the direction Z, routed along the edges of a third side surface 105, the first side surface 103, the first linkage surface 131, and the first support side surface 121, and electrically couples the first excitation electrode 21 to the first support electrode 23. On the other hand, the second draw-out wiring line 22a is disposed in the same manner as in the embodiment described above.

As described above, it is preferable that the first draw-out wiring line 21a is drawn from the first excitation electrode 21 toward the third side surface 105, which is the surface opposite from the second side surface 104, and that the second draw-out wiring line 22a is drawn from the second excitation electrode 22 toward the second side surface 104. According to the configuration described above, the first draw-out wiring line 21a and the second draw-out wiring line 22a are drawn in opposite directions, so that the first draw-out wiring line 21a and the second draw-out wiring line 22a can be separate from each other, whereby formation of parasitic capacitance can be suppressed.

Still instead, the first draw-out wiring line 21a may be drawn toward the second side surface 104, and the second draw-out wiring line 22a may be drawn toward the third side surface 105.

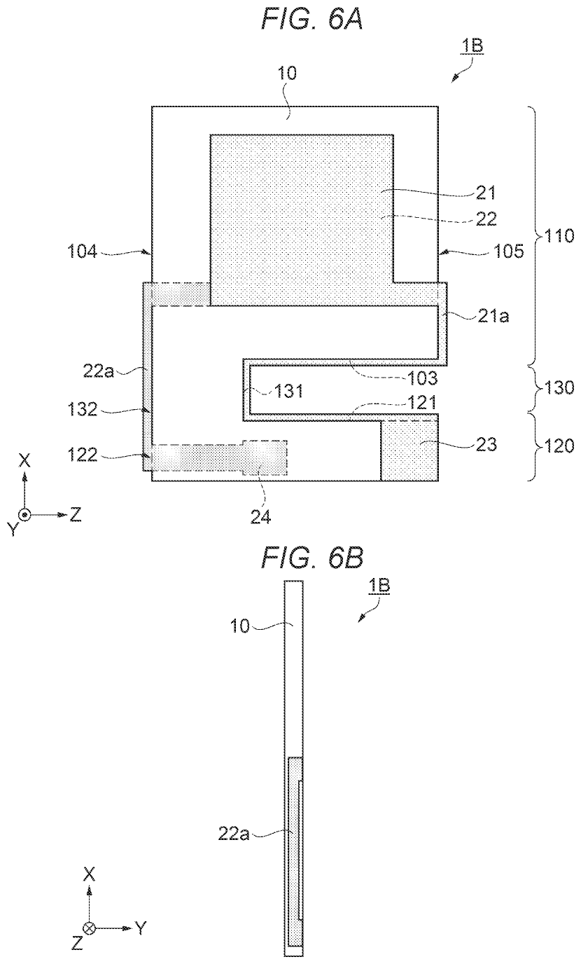

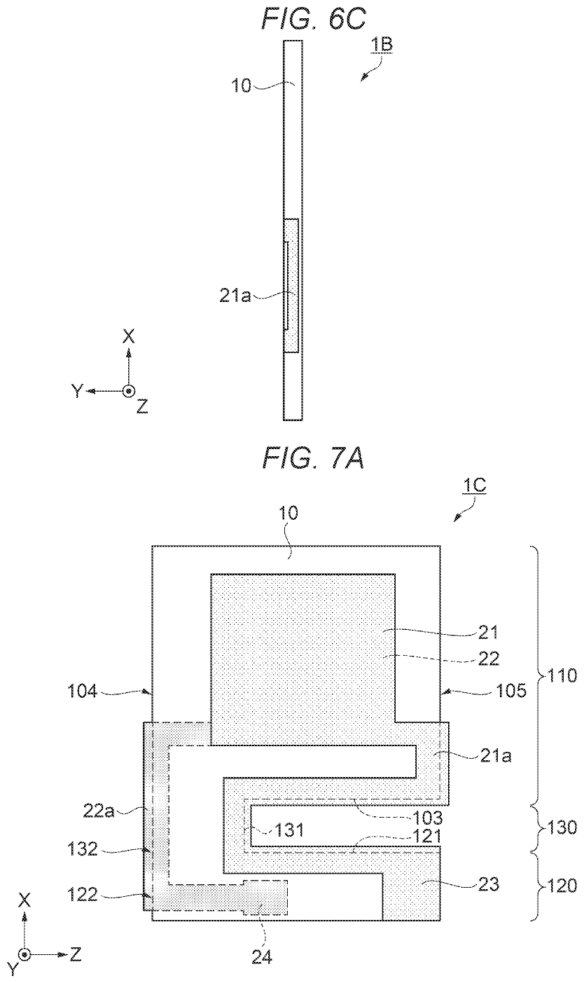

The first draw-out wiring line 21a of a vibrator 1B according to a variation shown in FIGS. 6A, 6B, and 6C is drawn from the first excitation electrode 21 toward the positive end of the direction Z, routed along the third side surface 105, the first side surface 103, the first linkage surface 131, and the first support side surface 121, which are side surfaces, and electrically couples the first excitation electrode 21 to the first support electrode 23. On the other hand, the second draw-out wiring line 22a is drawn from the second excitation electrode 22 toward the negative end of the direction Z, routed along the second side surface 104, the second linkage surface 132, and the second support side surface 122, which are side surfaces, and electrically couples the second excitation electrode 22 to the second support electrode 24.

As described above, it is preferable that the first draw-out wiring line 21a is provided at the third side surface 105, and that the second draw-out wiring line 22a is provided at the second side surface 104. According to the configuration described above, since the draw-out wiring lines 21a and 22a are formed at the second side surface 104 and the third side surface 105, respectively, so that the draw-out wiring lines 21a and 22a are disposed at surfaces different from the surfaces at which the first excitation electrode 21 and the second excitation electrode 22 are disposed, whereby the effect of the vibration induced at the surfaces on the draw-out wiring lines 21a and 22a can be suppressed.

Still instead, the first draw-out wiring line 21a may be drawn to the second side surface 104, and the second draw-out wiring line 22a may be drawn to the third side surface 105, the first side surface 103, the first linkage surface 131, and the first support side surface 121.

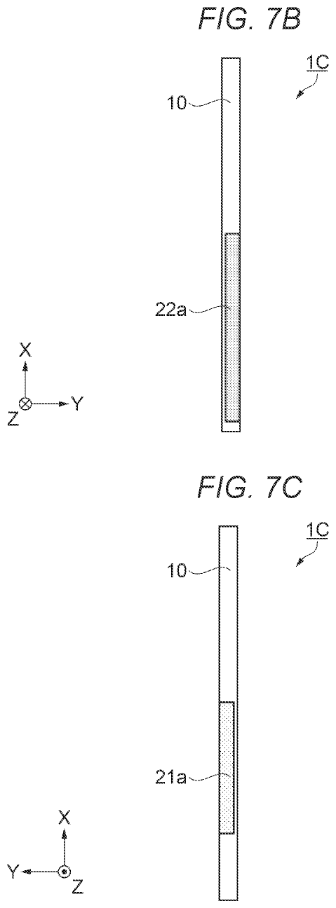

The first draw-out wiring line 21a of a vibrator 1C according to a variation shown in FIGS. 7A, 7B, and 7C is drawn from the first excitation electrode 21 toward the positive end of the direction Z, routed along both the surfaces along the edges of the third side surface 105, the first side surface 103, the first linkage surface 131, and the first support side surface 121 and these side surfaces, and electrically couples the first excitation electrode 21 to the first support electrode 23. On the other hand, the second draw-out wiring line 22a is drawn from the second excitation electrode 22 toward the negative end of the direction Z, routed along both the surfaces along the edges of the second side surface 104, the second linkage surface 132, and the second support side surface 122 and these side surfaces, and electrically couples the second excitation electrode 22 to the second support electrode 24.

As described above, the configuration in which the draw-out wiring lines 21a and 22a are disposed at the first principal surface 101, the second principal surface 102, and the side surfaces allows an increase in the area of the draw-out wiring lines 21a and 22a, so that the wiring resistance can be reduced, whereby the CI value can be lowered.

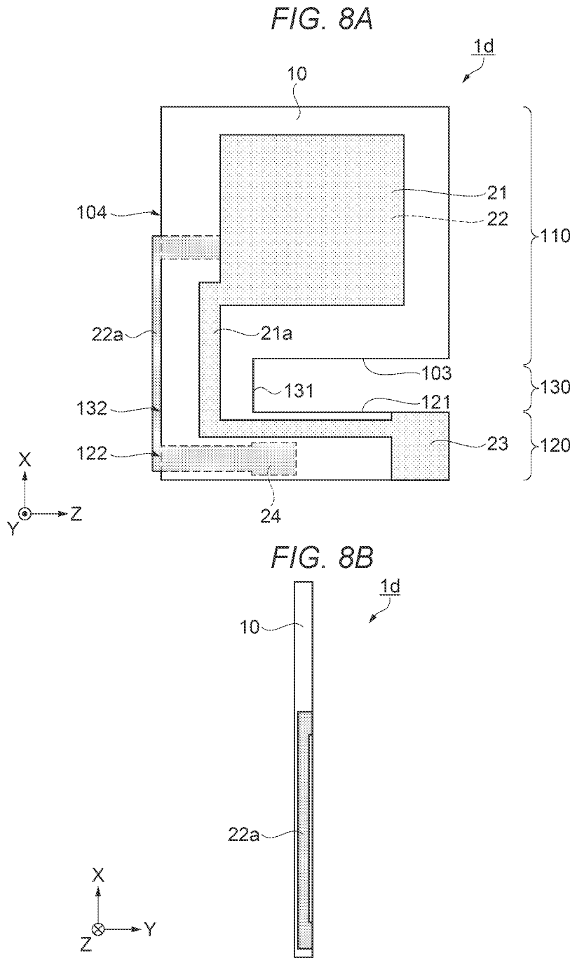

The first draw-out wiring line 21a of a vibrator 1D according to a variation shown in FIGS. 8A and 8B is disposed in the same manner as in the embodiment described above. On the other hand, the second draw-out wiring line 22a is drawn from the second excitation electrode 22 toward the negative end of the direction Z, routed along the second side surface 104, the second linkage surface 132, and the second support side surface 122, which are side surfaces, and electrically couples the second excitation electrode 22 to the second support electrode 24.

As described above, it is preferable that the second draw-out wiring line 22a is provided at the second side surface 104. According to the configuration described above, since the second draw-out wiring line 22a, which is one of the first draw-out wiring line 21a and the second draw-out wiring line 22a, is disposed at the second side surface 104, whereby the effect of the vibration induced at the second principal surface 102 can be suppressed. Instead, the first draw-out wiring line 21a may be drawn to the second side surface 104, and the second draw-out wiring line 22a may be disposed in the same manner as in the embodiment described above.

It is further preferable that the first draw-out wiring line 21a and the second draw-out wiring line 22a each include a ground layer made of chromium and an electrode layer made of gold, that the thickness of the ground layer is greater than or equal to 1 nm but smaller than or equal to 5 nm, and that the thickness of the electrode layer is greater than or equal to 100 nm but smaller than or equal to 500 nm.

According to the configuration described above, even in a configuration in which drawing the draw-out wiring lines 21a and 22a in the direction Z to suppress the effect of the thickness-shear vibration induced in the direction X lengthens the draw-out wiring lines 21a and 22a, the wiring resistance can be reduced by the ground layer having the thickness described above. An increase in the resistance value, such as the CI value, can therefore be suppressed.

What is claimed is:

1. A vibrator comprising:
a vibrator section that has a first principal surface, a second principal surface that is opposite from the first principal surface, a first side surface that couples the first principal surface and the second principal surface to each other and extends along a first direction, and a second side surface that couples the first principal surface and the second principal surface to each other and extends along a second direction that intersects with the first direction;
a support section that is disposed at a distance from the vibrator section and has a first support side surface facing the first side surface of the vibrator section and extending along the first direction and a second support side surface extending along the second direction;
a linkage section that has a first linkage surface coupled to the first side surface and the first support side surface and a second linkage surface coupled to the second side surface and the second support side surface;
a first excitation electrode that is provided at the first principal surface;
a second excitation electrode that is provided at the second principal surface and induces along with the first excitation electrode thickness-shear vibration that vibrates along the second direction;
a first support electrode that is provided at the support section and electrically coupled to the first excitation electrode;
a second support electrode that is provided at the support section and electrically coupled to the second excitation electrode;
a first draw-out wiring line that is drawn from the first excitation electrode along the first direction and electrically couples the first excitation electrode to the first support electrode; and
a second draw-out wiring that is drawn from the second excitation electrode along the first direction and electrically couples the second excitation electrode to the second support electrode.

2. The vibrator according to claim 1,
wherein the first draw-out wiring line is drawn from the first excitation electrode toward the second side surface, and
the second draw-out wiring line is drawn from the second excitation electrode toward the second side surface.

3. The vibrator according to claim 1,
where the first draw-out wiring line is drawn from the first excitation electrode toward a third side surface that is a surface opposite from the second side surface, and
the second draw-out wiring line is drawn from the second excitation electrode toward the second side surface.

4. The vibrator according to claim 3,
wherein the first draw-out wiring line is provided at the third side surface, and
the second draw-out wiring line is provided at the second side surface.

5. The vibrator according to claim 2,
wherein the second draw-out wiring line is provided at the second side surface.

6. The vibrator according to claim 1,
wherein the first draw-out wiring line and the second draw-out wiring line each include a ground layer made of chromium and an electrode layer made of gold,
a thickness of the ground layer is greater than or equal to 1 nm but smaller than or equal to 5 nm, and
a thickness of the electrode layer is greater than or equal to 100 nm but smaller than or equal to 500 nm.

7. A vibrator device comprising:
the vibrator according to claim 1;
a base on which the vibrator is mounted; and
a container that houses the vibrator,
wherein the support section of the vibrator is joined to the base via a joining material.

8. The vibrator device according to claim 7,
wherein the joining material includes a first electrically conductive adhesive that electrically couples the first excitation electrode provided at the first principal surface to the base, and a second electrically conductive adhesive that electrically couples the second excitation electrode provided at the second principal surface to the base.
